(19) United States
(12) Patent Application Publication
(10) Pub. No.: US 2012/0208335 A1
(43) Pub. Date: Aug. 16, 2012

(54) METHODS OF FABRICATING A SEMICONDUCTOR DEVICE HAVING LOW CONTACT RESISTANCE

(75) Inventors: Kyong Bong ROUH, Icheon-si (KR); Ho Jin CHO, Seongnam-si (KR); Yong Soo JOUNG, Icheon-si (KR)

(73) Assignee: HYNIX SEMICONDUCTOR INC., Icheon-si (KR)

(21) Appl. No.: 13/396,355

(22) Filed: Feb. 14, 2012

(30) Foreign Application Priority Data
Feb. 15, 2011 (KR) 10-2011-0013464

(51) Int. Cl. H01L 21/8238

(52) U.S. Cl. 438/232; 257/E21.634

(57) ABSTRACT

Methods of fabricating a semiconductor device are provided. The method includes forming a first gate stack and a second gate stack on a first region and a second region of a substrate, respectively. The method may further comprise forming first impurity regions self-aligned with the first gate stack and second impurity regions self-aligned with the second gate stack in the substrate of the first region and in the substrate of the second region, respectively. First impurity ions may be injected into the first and second impurity regions, forming a mask pattern covering the first region and exposing the second region on the substrate where the first impurity ions are injected and second impurity ions having an opposite conductivity type to the first impurity ions may be injected into the second impurity regions exposed by the mask pattern using a plasma doping process. The mask pattern may then be removed.

### CROSS-REFERENCES TO RELATED APPLICATIONS

The present application claims priority under 35 U.S.C 119(a) to Korean Application No. 10-2011-0013464, filed on Feb. 15, 2011, in the Korean intellectual property Office, which is incorporated by reference in its entirety.

### BACKGROUND

Exemplary embodiments of the present disclosure relate to methods of fabricating a semiconductor device and, more particularly, to methods of fabricating a semiconductor device having low contact resistance.

Complementary metal-oxide-semiconductor (CMOS) integrated circuits are used to reduce power consumption of semiconductor devices. The CMOS integrated circuits include N-channel MOS (NMOS) transistors and P-channel MOS (PMOS) transistors disposed in and on a substrate. The PMOS transistors and the NMOS transistors may be disposed in a PMOS transistor region and a NMOS transistor region, respectively. The PMOS transistor region may include P-type source and drain regions disposed in the substrate and a first gate insulation layer and a first gate conductive layer sequentially stacked on a P-channel region between the P-type source and drain regions. Similarly, the NMOS transistor region may include N-type source and drain regions disposed in the substrate and a second gate insulation layer and a second gate conductive layer sequentially stacked on an N-channel region between the N-type source and drain regions.

As described above, impurity regions (e.g., the P-type source and drain regions) in the PMOS transistor region may have a different conductivity type than impurity regions (e.g., the N-type source and drain regions) in the NMOS transistor region. Thus, while an ion implantation process is performed to form the impurity regions in one region of the PMOS transistor region and one region of the NMOS transistor region, other regions should be covered with a mask to prevent impurity ions from being implanted into the substrate of the other region. Otherwise, the impurity regions formed in the other region may be counter-doped with undesired impurities, thereby degrading electrical characteristics of the transistors formed in the other region. This phenomenon may also occur in contact implantation processes (for reducing contact resistances) performed after formation of the impurity regions (e.g., source/drain regions).

Specifically, the P-type source and drain regions and the N-type source and drain regions may be connected to metal contact plugs. In this case, to obtain ohmic contact between the metal contact plugs and the P-type source/drain regions and between the metal contact plugs and the N-type source/drain regions, the P-type source/drain regions may be heavily doped with P-type impurities and the N-type source/drain regions may also be heavily doped with N-type impurities. While a first contact implantation process for increasing a surface concentration of the P-type source/drain regions in the PMOS transistor region is performed, the NMOS region may be covered with a first mask to prevent the P-type impurity ions from being implanted into the substrate of the NMOS transistor region. Similarly, while a second contact implantation process for increasing a surface concentration of the N-type source/drain regions in the NMOS transistor region is performed, the PMOS region may be covered with a second mask to prevent the N-type impurity ions from being implanted into the substrate of the PMOS transistor region.

In general, the first and second masks may be formed using photoresist layers. Thus, each of the first and second masks may be formed using an exposure step and a development step. That is, two different and separate photolithography processes may be required to form the P-type source/drain regions and the N-type source/drain regions. In addition, the first mask should be removed after the P-type source/drain regions are formed, and the second mask should be removed after the N-type source/drain regions are formed. Accordingly, since two different masks are required to form the P-type source/drain regions and the N-type source/drain regions, the number of process steps and fabrication cost may increase.

### SUMMARY

Exemplary embodiments are directed to methods of fabricating a semiconductor device having low contact resistance.

In an exemplary embodiment, a method of fabricating a semiconductor device includes forming a first gate stack and a second gate stack on a first region and a second region of a substrate, respectively. An exemplary embodiment may also comprise forming first impurity regions self-aligned with the first gate stack and second impurity regions self-aligned with the second gate stack in the substrate of the first region and in the substrate of the second region, respectively. First impurity ions may be injected into the first and second impurity regions. A mask pattern may be formed to cover the first region while exposing the second region on the substrate where the first impurity ions are injected. Second impurity ions having an opposite conductivity type to the first impurity ions may be injected into the second impurity regions exposed by the mask pattern using, for example, a plasma doping process. The mask pattern may be removed after injecting the second impurity ions.

The first region and the second region may correspond to an NMOS transistor region and a PMOS transistor region, respectively.

The first impurity regions may be N-type source/drain regions and the second impurity regions may be P-type source/drain regions.

Injecting the first impurity ions may be performed by a blanket ion implantation process without use of any photo masks.

The first impurity ions may be phosphorus ions. The phosphorus ions may be injected at a dose of about 1×10¹⁴ atoms/cm² to about 1×10¹⁵ atoms/cm².

The second impurity ions may be boron ions.

The plasma doping process may be adjusted such that the second impurity ions are injected at a dose of about 2×10¹⁶ atoms/cm² to about 2×10¹⁸ atoms/cm².

The plasma doping process may be performed with energy of about 100 eV to about 5 KeV.

The method may further include applying a thermal treatment process to the substrate after removal of the mask pattern. The thermal treatment process may be performed at a temperature of about 600° C. to about 800° C. for about 15 seconds to about 30 seconds.

### BRIEF DESCRIPTION OF THE DRAWINGS

The above and other aspects, features, and other advantages will be more clearly understood from the following detailed description taken in conjunction with the accompanying drawings, in which:

FIGS. 1 to 4 are cross sectional views illustrating methods of fabricating semiconductor devices according to some exemplary embodiments.

FIGS. 5 and 6 are graphs illustrating contact resistance characteristics of semiconductor devices fabricated according to some exemplary embodiments and contact resistance characteristics of conventional semiconductor devices.

### DESCRIPTION OF SPECIFIC EMBODIMENTS

FIGS. 1 to 4 are cross sectional views illustrating methods of fabricating semiconductor devices according to some exemplary embodiments.

Referring to FIG. 1, a first gate stack and a second gate stack may be formed on a substrate 110 having a first region 101 and a second region 102. The first gate stack may be formed on the substrate 110 in the first region 101, and the second gate stack may be formed on the substrate 110 in the second region 102. The first region 101 may correspond to an NMOS transistor region and the second region 102 may correspond to a PMOS transistor region. The first gate stack may be formed to include a first gate insulation layer pattern 141 and a first gate conductive layer pattern 151 sequentially stacked on the substrate 110, and the second gate stack may be formed to include a second gate insulation layer pattern 142 and a second gate conductive layer pattern 152 sequentially stacked on the substrate 110.

First impurity regions, for example, first source/drain regions 121 may be formed in the substrate 110 in the first region 101 and may be aligned with the first gate stack 141 and 151. That is, the first source/drain regions 121 may be formed using an ion implantation process that employs the first gate stack 141 and 151 as an ion implantation mask. The first source/drain regions 121 may be heavily doped with N-type impurities. The substrate 110 between the first source/drain regions 121 may correspond to a first channel region 131. That is, the first channel region 131 may be disposed under the first gate stack 141 and 151.

Second impurity regions, for example, second source/drain regions 122, may be formed in the substrate 110 in the second region 102 and may be aligned with the second gate stack 142 and 152. That is, the second source/drain regions 122 may be formed using an ion implantation process that employs the second gate stack 142 and 152 as an ion implantation mask. The second source/drain regions 122 may be heavily doped with P-type impurities. The substrate 110 between the second source/drain regions 122 may correspond to a second channel region 132. That is, the second channel region 132 may be disposed under the second gate stack 142 and 152.

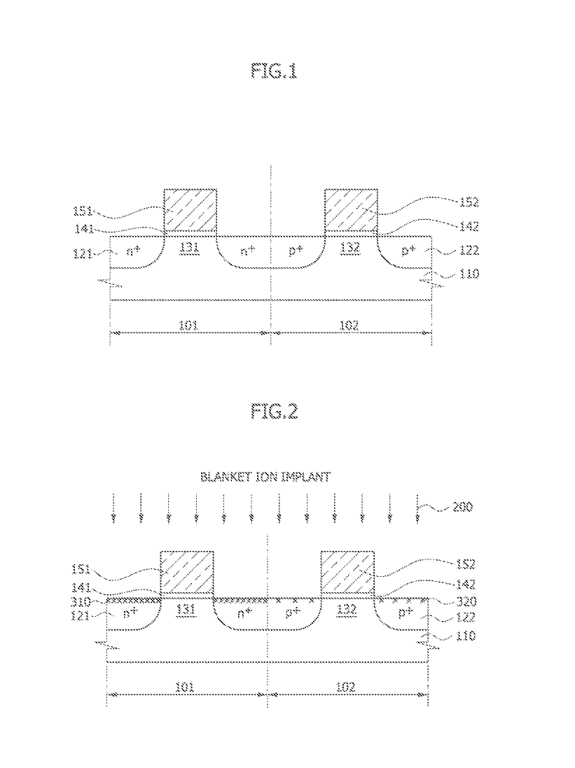

Referring to FIG. 2, N-type impurities, for example, phosphorus ions, may be implanted into the substrate 110 using a blanket ion implantation process as indicated by arrows 200. As a result of the blanket ion implantation process, first impurity injection layers 310 for reducing contact resistance may be formed under surfaces of the first source/drain regions 121 and second impurity injection layers 320 may be formed under surfaces of the second source/drain regions 122. Since the first source/drain regions 121 are N-type regions having the same conductivity type as the phosphorus ions used in the blanket ion implantation process, an impurity concentration of the first impurity injection layers 310 may be equal to or higher than an initial surface impurity concentration of the first source/drain regions 121. In contrast, since the second source/drain regions 122 are P-type regions with an opposite conductivity type to the phosphorus ions used in the blanket ion implantation process, an impurity concentration of the second impurity injection layers 320 may be lower than an initial surface impurity concentration of the second source/drain regions 122.

In a typical case, when the first impurity injection layers 310 are formed, the second region 102 may be covered with a mask pattern. However, according to the presently described embodiment, the first impurity injection layers 310 may be formed by the blanket ion implantation process without use of any mask patterns. Thus, the initial surface impurity concentration of the second source/drain regions 122 may be lowered due to the second impurity injection layers 320, as described above. In this case, contact resistance characteristics of the second source/drain regions 122 may be degraded. Accordingly, an additional doping process may be required to selectively inject P-type impurities into the second source/drain regions 122 in the second regions 102. If the additional doping process is performed, the second impurity injection layers 320 may be counter-doped. Thus, the surface concentration of the second source/drain regions 122 may be increased to improve the contact resistance characteristic of the second source/drain regions 122. If the impurity concentration of the second impurity injection layers 320 having an N-type is relatively too high, the second impurity injection layers 320 may not be sufficiently counter-doped even with an additional doping process. Hence, the blanket ion implantation process may be performed with a dose of about 1×10¹⁴ atoms/cm² to about 1×10¹⁵ atoms/cm².

A surface concentration of a phosphorus (P) layer in a silicon substrate may be increased after thermal oxidation, whereas a surface concentration of an arsenic (As) layer in a silicon substrate may be reduced after thermal oxidation. These phenomena may be due to segregation coefficients of the phosphorus (P) atoms and the arsenic (As) atoms. Thus, the dose of the phosphorus ions when the blanket ion implantation process is performed using the phosphorus ions may be less than the dose of the arsenic ions when the blanket ion implantation process is performed using the arsenic ions. For example, if the blanket ion implantation process is performed using the phosphorus ions instead of the arsenic ions, the dose of the phosphorus ions may correspond from about 20% to about 50% of the dose of the arsenic ions. In the event that the arsenic ions are used in the blanket ion implantation process, the dose of the arsenic ions may be reduced to enhance the counter-doping effect of the second impurity injection layers 320 in a subsequent process. In this case, the contact resistance of the first source/drain regions 121 may be increased whereas the second impurity injection layers 320 are more readily counter-doped in a subsequent process. That is, it may be difficult to optimize the blanket ion implantation process. However, in the event that the phosphorus ions are used in the blanket ion implantation process, the surface concentration of the first source/drain regions 121 may be increased due to the segregation coefficient of the phosphorus ions even though the dose of the phosphorus ions is lowered from about 20% to about 50% of the dose of the arsenic ions. Thus, both the first source/drain regions 121 and the second source/drain regions 122 may exhibit excellent contact resistance characteristics.

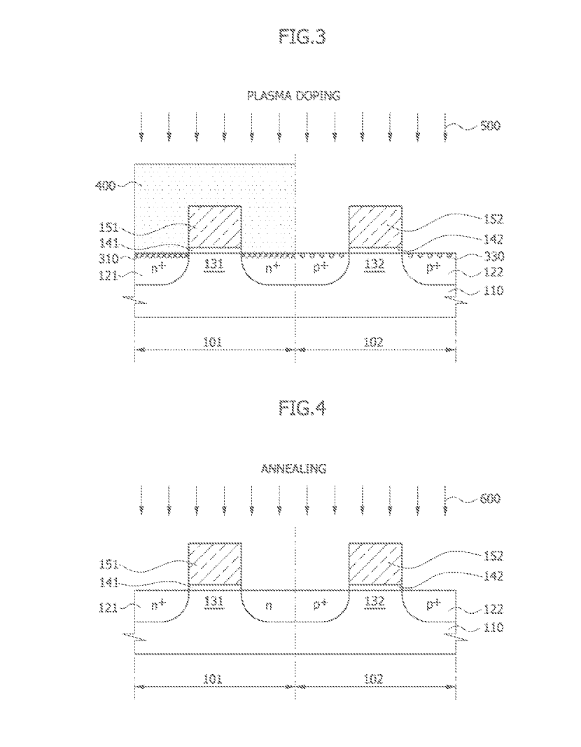

Referring to FIG. 3, a mask pattern 400 may be formed to cover the first region 101 and to expose the second region 102. The mask pattern 400 may be formed of a photoresist pattern. Specifically, the mask pattern 400 may be formed by coating a photoresist layer on an entire surface of the substrate including the first and second impurity injection layers 310 and 320 and by selectively removing the photoresist layer in the second region 102 using an exposure step and a development step. Subsequently, a plasma doping process may be performed to inject P-type impurities into the second source/drain regions 122 of the second region 102, as indicated by arrows 500 in FIG. 3. The plasma doping process may be performed using a diborane (B₂H₆) gas as a source gas, and boron ions generated from the diborane gas may be injected at a dose of about 2×10¹⁶ atoms/cm² to about 2×10¹⁸ atoms/cm². Further, the plasma doping process may be performed with energy of about 100 eV to about 5 KeV. During the plasma doping process, the second impurity injection layers 320 (FIG. 2) doped with phosphorus ions in the second region 102 may be counter-doped with boron ions. As a result of the plasma doping process, P-type third impurity injection layers 330 may be formed at the surfaces of the second source/drain regions 122.

Referring to FIG. 4, the mask pattern 400 (FIG. 3) may be removed using a typical strip process such as an ashing process. A thermal treatment process may be performed, as indicated by arrows 600 in FIG. 4. The thermal treatment process may be performed to activate the phosphorus ions and the boron ions injected into the first and second source/drain regions 121 and 122. The thermal treatment process may be performed using, for example, a rapid thermal processing (RTP) method. In an embodiment, the rapid thermal processing (RTP) method may be performed at a temperature of about 600° C. to about 800° C. for about 15 seconds to about 30 seconds. Although not shown in the drawings, first metal contact plugs and second metal contact plugs may be formed on the first source/drain regions 121 and the second source/drain regions 122, respectively. In an embodiment, metal silicide layers may be formed on the first and second source/drain regions 121 and 122 prior to formation of the first and second metal contact plugs.

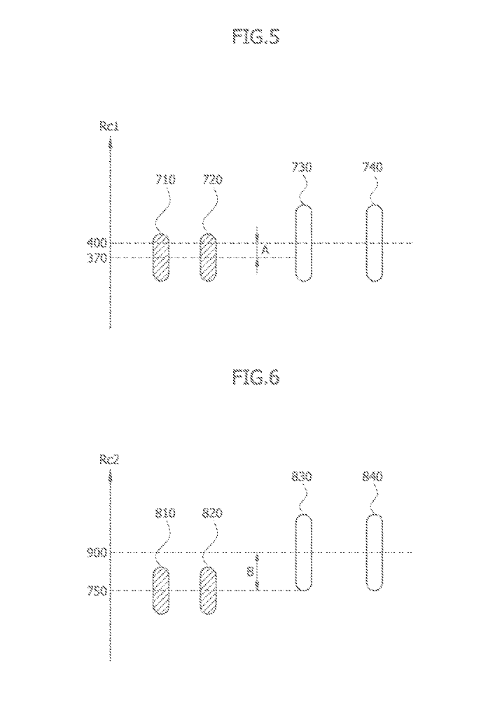

FIGS. 5 and 6 are graphs illustrating contact resistance characteristics of semiconductor devices fabricated according to some exemplary embodiments and contact resistance characteristics of the conventional semiconductor devices.

Referring to FIG. 5, contact resistances Rc1 of the first source/drain regions 121 (e.g., N-type source/drain regions) are indicated by reference numerals 710, 720, 730 and 740. The data indicated by the reference numerals 710 and 720 correspond to the contact resistances of the conventional semiconductor devices fabricated using two separate photo masks, and the data indicated by the reference numerals 730 and 740 correspond to the contact resistances of the semiconductor devices fabricated using a single photo mask according to an exemplary embodiment. That is, the semiconductor devices showing the data indicated by the numerals 730 and 740 were fabricated using a blanket ion implantation process and a plasma doping process. As seen from FIG. 5, an average contact resistance of the N-type source/drain regions of the conventional semiconductor devices was about 370 ohms, and an average contact resistance of the N-type source/drain regions fabricated according to an exemplary embodiment was about 400 ohms. An average difference A between the N-type contact resistance of the conventional semiconductor devices and the N-type contact resistance of the semiconductor devices according to the exemplary embodiments were about 30 ohms, which is within the allowable range.

Referring to FIG. 6, contact resistances Rc2 of the second source/drain regions 122 (e.g., P-type source/drain regions) are indicated by reference numerals 810, 820, 830 and 840. The data indicated by the reference numerals 810 and 820 correspond to the contact resistances of the conventional semiconductor devices fabricated using two separate photo masks, and the data indicated by the reference numerals 830 and 840 correspond to the contact resistances of the semiconductor devices fabricated using a single photo mask according to an exemplary embodiment. That is, the semiconductor devices showing the data indicated by the numerals 830 and 840 were fabricated using a blanket ion implantation process and a plasma doping process. As can be seen from FIG. 6, an average contact resistance of the P-type source/drain regions of the conventional semiconductor devices was about 750 ohms, and an average contact resistance of the P-type source/drain regions fabricated according to the exemplary embodiment was about 900 ohms. That is, an average difference B between the P-type contact resistance of the conventional semiconductor devices and the P-type contact resistance of the semiconductor devices according to the exemplary embodiments were about 150 ohms, which is within the allowable range. In particular, even though the contact resistance of the P-type contact resistance is increased by about 150 ohms, saturation current characteristics of the PMOS transistors fabricated according to the exemplary embodiments were not degraded.

According to the exemplary embodiments set forth above, a contact implantation process for increasing surface concentrations of N-type impurity regions and P-type impurity regions may be performed using a blanket implantation step and a plasma doping step with a single photo mask. Thus, fabrication cost can be reduced and the number of process steps can also be reduced. In particular, when the blanket implantation step is performed using phosphorus ions instead of arsenic ions, an ion dose of the blanket implantation step may be reduced without degradation of contact resistance characteristics.

The exemplary embodiments of the inventive concept have been disclosed above for illustrative purposes. Those skilled in the art will appreciate that various modifications, additions, and substitutions are possible without departing from the scope and spirit of the inventive concept as disclosed in the accompanying claims.

What is claimed is:

1. A method of fabricating a semiconductor device, the method comprising:
forming a first gate stack and a second gate stack on a first region and a second region of a substrate, respectively;
forming first impurity regions self-aligned with the first gate stack and second impurity regions self-aligned with the second gate stack in the substrate of the first region and in the substrate of the second region, respectively;
injecting first impurity ions into the first and second impurity regions;
forming a mask pattern covering the first region and exposing the second region on the substrate where the first impurity ions are injected;
injecting second impurity ions having an opposite conductivity type to the first impurity ions into the second impurity regions exposed by the mask pattern using a plasma doping process; and
removing the mask pattern.

2. The method of claim 1, wherein the first region and the second region correspond to an NMOS transistor region and a PMOS transistor region, respectively.

3. The method of claim 1, wherein the first impurity regions are N-type source/drain regions and the second impurity regions are P-type source/drain regions.

4. The method of claim 1, wherein injecting the first impurity ions is performed by a blanket ion implantation process without use of any photo masks.

5. The method of claim 1, wherein the first impurity ions are phosphorus ions.

6. The method of claim 5, wherein the phosphorus ions are injected at a dose of about 1×10¹⁴ atoms/cm² to about 1×10¹⁵ atoms/cm².

7. The method of claim 1, wherein the second impurity ions are boron ions.

8. The method of claim 1, wherein the plasma doping process is adjusted such that the second impurity ions are injected at a dose of about 2×10¹⁶ atoms/cm² to about 2×10¹⁸ atoms/cm².

9. The method of claim 1, wherein the plasma doping process is performed with energy of about 100 eV to about 5 KeV.

10. The method of claim 1, further comprising applying a thermal treatment process to the substrate after removal of the mask pattern.

11. The method of claim 10, wherein the thermal treatment process is performed at a temperature of about 600° C. to about 800° C. for about 15 seconds to about 30 seconds.
